(19) United States
(12) Patent Application Publication
(10) Pub. No.: US 2024/0113086 A1
(43) Pub. Date: Apr. 4, 2024

(54) DISPLAY UNIT, DISPLAY DEVICE AND MANUFACTURING METHOD THEREOF

(71) Applicant: Xiamen Extremely PQ Display Technology Co., Ltd., Xiamen (CN)

(72) Inventor: YONG FAN, Xiamen (CN)

(21) Appl. No.: 18/525,060

(22) Filed: Nov. 30, 2023

Related U.S. Application Data
(63) Continuation of application No. PCT/CN2022/071498, filed on Jan. 12, 2022.

(51) Int. Cl. H01L 25/075; H01L 33/62

(52) U.S. Cl. CPC H01L 25/0753; H01L 33/62; H01L 2933/0066

(57) ABSTRACT

A display unit, a display device and a manufacturing method thereof are provided. The display unit includes: a transparent patterned substrate layer, which defines a via; multiple micro light-emitting components disposed on the transparent patterned substrate layer and electrically connected thereto; a circuit connection layer disposed in the via of the transparent patterned substrate layer and electrically connected thereto; and a circuit bonding layer disposed on a side of the circuit connection layer facing away from the multiple micro light-emitting components and electrically connected to the circuit connection layer. The transparent patterned substrate layer defines the via therein to directly and electrically connect to an external drive circuit such as a panel drive circuit by the circuit connection layer in the via and the circuit bonding layer electrically connected to the circuit connection layer, thus avoiding problems of side-manufactured circuit and circuit breakage due to flexible bending.

### CROSS-REFERENCE TO RELATED APPLICATION

This application is a continuation of International Application No. PCT/CN2022/071498, filed on Jan. 12, 2022, the disclosure of which is incorporated herein by reference in its entirety.

### TECHNICAL FIELD

The disclosure relates to the field of display technologies, and more particularly to a display unit, a display device and a manufacturing method thereof.

### BACKGROUND

Micro-light emitting diode (Micro-LED) display device is regarded as a new-type display technology with the most development potential in the next generation because it combines advantages of an organic light-emitting diode (OLED) display device, such as thinness, flexibility, drop resistance, foldability, etc., and also has advantages of long service life, ultra-low power consumption, high responsiveness, high transparency, etc., which is in line with a future development tendency. In particular, the micro-LED can be seamlessly tiled through unit display modules to realize screen display in a super large scale, and therefore has wide application prospects in fields of large-size display such as command monitoring centers, business centers, high-end conferences, private cinema, etc.

However, an existing tiled display screen (i.e., a display device) mainly uses a method of manufacturing a printed circuit on a side thereof to connect to a drive circuit (i.e., a transparent patterned substrate layer) and a drive chip (i.e., a panel drive circuit) of the micro-LED or uses a flexible bending substrate and a flexible circuit manufactured on the flexible bending substrate to realize bonding between the drive circuit and the drive chip. The former method needs to install the printed circuit on the side surface, the process of which is complex, costs much, and exists risks of circuit scratch and circuit breakage caused by extrusion during assembling the display screen. Meanwhile, the latter method requires ultra-narrow bonding technology and has high requirements for bonding machines. Moreover, the flexible circuit needs to be bent, which can easily lead to circuit breakage and affects yield issues of the display screen.

### SUMMARY

In order to solve at least some defects existed in the related art, embodiments of the disclosure provide a display unit, a display device and a manufacturing method thereof. In the disclosure, a transparent patterned substrate layer defines a via, and then the transparent patterned substrate layer can be electrically connected to an external panel drive circuit through a circuit connection layer in the via and a circuit bonding layer electrically connected to the circuit connection layer, thereby avoiding problems that the circuit needs to be manufactured on a side of the display unit, and the circuit is easy to break after flexible bending.

Specifically, in a first aspect, an embodiment of the disclosure provides a display unit, including: a transparent patterned substrate layer, multiple micro light-emitting components, a first circuit connection layer, and a first circuit bonding layer; the transparent patterned substrate layer defines a first via; the multiple micro light-emitting components are disposed on the transparent patterned substrate layer and electrically connected to the transparent patterned substrate layer; the first circuit connection layer is disposed in the first via of the transparent patterned substrate layer and electrically connected to the transparent patterned substrate layer; and the first circuit bonding layer is disposed on a side of the circuit connection layer facing away from the multiple micro light-emitting components and electrically connected to the first circuit connection layer.

In an embodiment of the disclosure, the display unit further includes: a packaging layer; and the packaging layer is disposed on the transparent patterned substrate layer and covers the multiple micro light-emitting components.

In an embodiment of the disclosure, the transparent patterned substrate layer includes: a first substrate and a drive control circuit layer; the first via penetrates through the first substrate; the drive control circuit layer is disposed on a side of the first substrate, and the drive control circuit layer is disposed between the first substrate and the multiple micro light-emitting components; the multiple micro light-emitting components are electrically connected to the drive control circuit layer; and the first circuit bonding layer is disposed on a side of the first substrate facing away from the drive control circuit layer, and the first circuit connection layer is electrically connected to the multiple micro light-emitting components through the drive control circuit layer.

In an embodiment of the disclosure, the transparent patterned substrate layer further defines a second via; the display unit further includes: a second circuit connection layer and a second circuit bonding layer; the second circuit connection layer is disposed in the second via of the transparent patterned substrate layer and is electrically connected to the transparent patterned substrate layer; and the second circuit bonding layer is disposed on a side of the second circuit connection layer facing away from the multiple micro light-emitting components and is electrically connected to the second circuit connection layer.

In an embodiment of the disclosure, the second via and the first via are disposed at two opposite ends of the transparent patterned substrate layer, and the multiple micro light-emitting components are disposed between the second via and the first via.

In addition, in a second aspect, an embodiment of the disclosure further provides a display device, including: a display substrate, a first bonding pad disposed on a side of the display substrate, and a first display unit as mentioned in any one of the foregoing embodiments; and the first display unit is disposed on the side of the display substrate, the first bonding pad is disposed corresponding to the first circuit bonding layer of the first display unit and is electrically connected to the first circuit bonding layer of the first display unit.

In an embodiment of the disclosure, the transparent patterned substrate layer of the first display unit further defines a second via, the second via and the first via are disposed on two opposite ends of the transparent patterned substrate layer, and the multiple micro light-emitting components are disposed between the second via and the first via; the first display unit further includes: a second circuit connection layer and a second circuit bonding layer; the second circuit connection layer is disposed in the second via of the transparent patterned substrate layer and is electrically connected to the transparent patterned substrate layer; the second circuit bonding layer is disposed on a side of the second circuit connection layer facing away from the multiple micro light-emitting components and is electrically connected to the second circuit connection layer; and the display device further includes a second bonding pad disposed on the side of the display substrate, and the second bonding pad is disposed corresponding to the second circuit bonding layer and is electrically connected to the second circuit bonding layer; and the display device further includes: a second display unit, the second display unit is also any one of the display units as mentioned in the foregoing embodiments, the second display unit is disposed on the side of the display substrate and is tiled with the first display unit, and the first circuit bonding layer of the second display unit is electrically connected to the second bonding pad.

In an embodiment of the disclosure, the display substrate further includes: a second substrate and a transparent conductive layer; the first display unit and the first bonding pad are disposed on a same side of the second substrate; the transparent conductive layer is disposed on the second substrate and disposed between the first bonding pad and the second substrate; and the transparent conductive layer is electrically connected to the first bonding pad.

In an embodiment of the disclosure, the display device further includes: a circuit protection layer, the circuit protection layer is disposed between the transparent conductive layer and the first display unit, the circuit protection layer covers the transparent conductive layer, and the first bonding pad penetrates through the circuit protection layer and is electrically connected to the first circuit bonding layer of the first display unit.

In an embodiment of the disclosure, the display device further includes: a buffer layer disposed between the circuit protection layer and the first display unit.

In an embodiment of the disclosure, the display device further includes: a panel drive circuit disposed on the side of the display substrate and electrically connected to the first bonding pad.

In addition, in a third aspect, a manufacturing method of the display device as mentioned in any one of the foregoing embodiments of the disclosure includes the following steps:

sequentially forming a compensation layer and a second substrate on a side of a glass substrate;

forming a transparent conductive layer on the second substrate;

forming a bonding pad on the transparent conductive layer, and the bonding pad being electrically connected to the transparent conductive layer;

bonding the first circuit bonding layer of the display unit as mentioned in any one of the foregoing embodiments to the bonding pad; and

separating the second substrate from the compensation layer.

The above technical solutions may have one or more of the following advantages or beneficial effects. In the display unit provided in any one of the embodiments of the disclosure, the transparent patterned substrate layer defines the first via, and then the transparent patterned substrate layer can be electrically connected to the panel drive circuit directly through the first circuit connection layer in the first via and the first circuit bonding layer electrically connected to the first circuit connection layer, thereby avoiding the problems that the circuit needs to be manufactured on the side of the display unit, and the circuit is easy to break after flexible bending, etc. The manufacturing process of the display unit according to the disclosure is simple, the cost thereof is low, and the service life of the display unit can also be prolonged, and the problems of circuit scratches and extrusion breakage in the assembly process are avoided. In addition, the disclosure further defines the second via and includes the second circuit connection layer disposed in the second via, as well as provides the electrical connection among the second circuit bonding layer, the second circuit connection layer, and the drive control circuit layer to realize the tiling with another display unit, thereby achieving the display screen with a larger size. Moreover, according to the display device provided in any one of the embodiments of the disclosure, the panel drive circuit and the drive control circuit layer are electrically connected through the circuit connection layer and the circuit bonding layer provided by the display unit, thereby to make a bonding area of the display device be disposed between the second substrate and the first substrate, and then the problems that the circuit needs to be manufactured on the side, and the circuit is easy to break after flexible bending are avoided, and therefore the transparent flexible display device is provided. Furthermore, the multiple display units and the panel drive circuit are bonded to the display substrate, and then the panel drive circuit can control the multiple display units, thereby reducing the driving cost of the display device. In addition, the circuit protection layer is provided on the transparent conductive layer to protect the transparent conductive circuit. Finally, the embodiment of the disclosure further provides the manufacturing method of the display device, by providing the compensation layer between the glass substrate and the flexible substrate, the problem of metal breakage caused by subsequent laser lift-off the glass is avoided, the flatness and cleanliness of the side, facing towards the glass substrate, of the flexible substrate after the laser lift-off operation are protected, and energy consumption is saved.

### BRIEF DESCRIPTION OF DRAWINGS

In order to illustrate technical solutions of the embodiments of the disclosure more clearly, attached drawings that need to be used in the embodiments are briefly described below. Apparently, the attached drawings described below are merely some of the embodiments of the disclosure, and for those skilled in the related art, other drawings can be obtained according to these drawings without involving any inventive effort.

FIG. 1 illustrates a schematic structural diagram of a display unit according to an embodiment 1 of the disclosure.

FIG. 2a illustrates a schematic structural diagram of another display unit according to the embodiment 1 of the disclosure.

FIG. 2b illustrates a schematic diagram of a position and a distribution of vias in the display unit illustrated in FIG. 1.

FIG. 2c illustrates another schematic diagram of a position and a distribution of vias in the display unit illustrated in FIG. 1.

FIG. 2d illustrates a schematic structural diagram of still another display unit according to the embodiment 1 of the disclosure.

FIG. 3 illustrates a schematic structural diagram of a display device according to an embodiment 2 of the disclosure.

FIG. 4 illustrates a schematic flowchart of a manufacturing method of the display device according to the embodiment 2 of the disclosure.

FIG. 5 illustrates a schematic flowchart of another manufacturing method of the display device according to the embodiment 2 of the disclosure.

FIG. 6 illustrates a schematic structural diagram of a display device according to an embodiment 3 of the disclosure.

### DETAILED DESCRIPTION OF EMBODIMENTS

The technical solutions of the embodiments of the disclosure will be clearly and completely described below with reference to the attached drawings of the embodiments of the disclosure. All other embodiments obtained by those skilled in the related art based on the embodiments of the disclosure without creative efforts shall fall within the scope of the protection of the disclosure.

### Embodiment 1

As shown in FIG. 1, the embodiment 1 of the disclosure provides a display unit 10. Specially, the display unit 10 includes a transparent patterned substrate layer 12, multiple micro light-emitting components 11, a first circuit connection layer 13, and a first circuit bonding layer 14.

Specifically, the transparent patterned substrate layer 12 is configured to provide a switch circuit or a drive circuit to the multiple micro light-emitting components 11 that are disposed on the transparent patterned substrate layer 12. The transparent patterned substrate layer 12 defines a first via V1. The multiple micro light-emitting components 11 are arranged in an array (or determinant), are disposed on the transparent patterned substrate layer 12, and are electrically connected to the transparent patterned substrate layer 12. In an illustrated embodiment, each of the multiple micro light-emitting components 11 can be a semiconductor light-emitting diode chip with a length, a width, and a thickness of less than 100 micrometers (nm), for example, each micro light-emitting component 11 can be a micro light-emitting diode (micro-LED) or a sub-millimeter light-emitting diode (mini-LED), or even another light-emitting component.

In an embodiment, the first circuit connection layer 13 is disposed in the first via V1 of the transparent patterned substrate layer 12; the first circuit connection layer 13 is made of at least one material selected from the group consisting of copper and aluminum; the first circuit connection layer 13 has good electrical conductivity, thereby achieving an electrical connection between an area that the first via V1 is in contact with the transparent patterned substrate layer 12 and the transparent patterned substrate layer 12. In an illustrated embodiment, the first circuit connection layer 13 is electrically connected to the multiple micro light-emitting components 11 through the transparent patterned substrate layer 12. In an embodiment, the first circuit bonding layer 14 is disposed on a side of the first circuit connection layer 13 facing away from the multiple micro light-emitting components 11, and the first circuit bonding layer 14 is electrically connected to the first circuit connection layer 13. In an illustrated embodiment, the first circuit bonding layer 14 is configured to provide a bonding end for an electrical connection between the display unit 10 and an external drive circuit, such as a panel drive circuit; and the first circuit bonding layer 14 is a conductive layer with good electrical conductivity that is made of at least one material selected from the group consisting of indium, tin, bismuth, silver and gold, or an anisotropic conductive film (also referred to as ACF adhesive). However, the disclosure is not limited thereto.

According to the technical solution, the first via V1 is defined on the transparent patterned substrate layer 12, and then the transparent patterned substrate layer 12 can directly and electrically connect to the external drive circuit, such as the panel drive circuit, through the first circuit connection layer 13 disposed in the first via V1 and the first circuit bonding layer 14 that is electrically connected to the first circuit connection layer 13, thereby avoiding problems that the circuit needs to be manufactured on a side of the display unit, and the circuit is easy to break after flexible bending, etc. Furthermore, a manufacturing process of the display unit according to the disclosure is simple, costs little, and improves a service life of the product (i.e., the display unit), and problems of circuit scratches and circuit breakage during an assembly process are avoided.

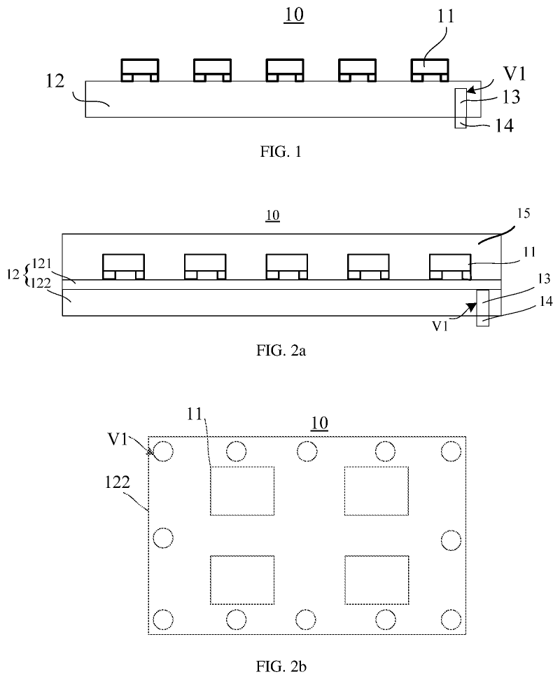

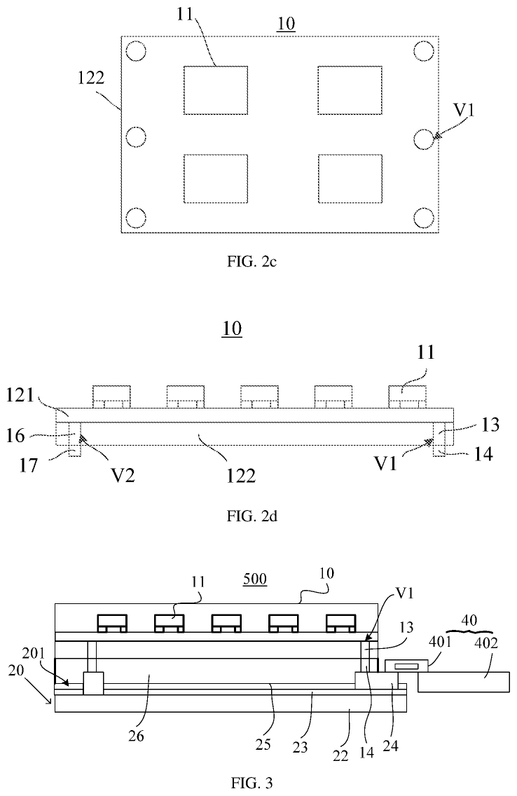

Further, as shown in FIG. 2a, the display unit 10 further includes a packaging layer 15. In an embodiment, the packaging layer 15 is disposed on the transparent patterned substrate layer 12 and covers the multiple micro light-emitting components 11. In an illustrated embodiment, the packaging layer 15 is made of a thermoplastic adhesive film, which can isolate external water and oxygen, effectively protecting the multiple micro light-emitting components 11. Moreover, in other embodiments of the disclosure, the packaging layer 15 can also be a flexible packaging layer. Specially, the flexible packaging layer can be made of a composite material such as a G-41 polymer (referred to as a new vinyl alcohol copolymer), and is used to package the multiple micro-LEDs to prevent the micro-LEDs from being eroded by the external water and oxygen. Furthermore, based on the material selected by the flexible packaging layer, the flexible packaging layer can be flexibly bent, which meets the needs of a flexible display screen. It should be understood that a protective cover plate (not shown in the attached drawings) may also be provided on the packaging layer 15, and the protective cover plate may be a rigid substrate such as glass substrate or a flexible substrate such as polyimide substrate, and the protective cover plate is used to further protect the display unit 10 or enhance a display effect of the display unit 10.

As shown in FIG. 2a, the transparent patterned substrate layer 12 further includes a first substrate 122 and a drive control circuit layer 121. In an embodiment, the first via V1 is defined on the first substrate 122 and penetrates through the first substrate 122. In an illustrated embodiment, the first substrate 122 can be a transparent substrate or a substrate with a good flexible transparent effect such as the polyimide substrate. Moreover, the drive control circuit layer 121 includes multiple thin film transistors arranged in an array, or even further includes other electrical components such as a storage capacitance. The multiple thin film transistors arranged in the array and the storage capacitance together form the switch circuit or the drive circuit of the multiple micro light-emitting components 11. In an illustrated embodiment, the above-mentioned switch circuit or the drive circuit is a circuit such as a 2T1C circuit (including 2 transistors and 1 capacitance, namely 2 thin film transistors and 1 storage capacitance abbreviated as Cst), a 3T1C circuit (including 3 transistors and 1 capacitance, namely 3 thin film transistors and 1 storage capacitance), a 4T1C circuit (including 4 transistors and 1 capacitance, namely 4 thin film transistors and 1 storage capacitance), a 4T2C circuit (including 4 transistors and 2 capacitances, namely 4 thin film transistors and 2 storage capacitances), etc.; however, the disclosure is not limited thereto.

Specifically, the drive control circuit layer 121 is disposed between the first substrate 122 and the multiple micro light-emitting components 11. The multiple micro light-emitting components 11 are disposed on the drive control circuit layer 121 in the array mode and are electrically connected to the drive control circuit layer 121. The first circuit bonding layer 14 is disposed on a side of the first circuit connection layer 13 facing away from the drive control circuit layer 121. The first circuit connection layer 13 is electrically connected to the multiple micro light-emitting components 11 through the drive control circuit layer 121, and the first circuit bonding layer 14 is electrically connected to the first circuit connection layer 13.

Specifically, the first via V1 can also set to be multiple. In an illustrated embodiment, the first circuit connection layer 13 includes multiple bonding pads, the multiple bonding pads are correspondingly disposed in the multiple first vias V1, and the multiple bonding pads are electrically connected to the drive control circuit layer 121. Furthermore, each bonding pad is correspondingly provided with the first circuit bonding layer 14 electrically connected thereto.

It should be noted that the embodiments of the disclosure do not define a specific structure and type of the drive control circuit layer 121, namely that the types or structures of the thin film transistor and the storage capacitance are not defined, which will not be repeated here. In a specific implementation, as long as the drive control circuit layer 121 is reasonably configured, it can be used to implement the driving or switching functions of the multiple micro light-emitting components 11. Typically, the thin film transistor may be, for example, a polysilicon transistor, an amorphous silicon transistor, an organic thin film transistor, a metal oxide transistor, a carbon nanotube or a graphene transistor, another transistor in a nanoparticle scale, etc., which is not limited in the embodiments of the disclosure.

Further, the multiple first vias V1 can be disposed at edges of the display unit 10. In an illustrated embodiment, when a shape of the display unit 10 is rectangular, the multiple first vias V1 can be disposed around the first substrate 122 (as shown in FIG. 2b); the multiple first vias V1 may also be respectively disposed at two opposite ends of the first substrate 122 (as shown in FIG. 2c), etc.; and as shown in FIG. 2d, the first substrate 122 of the transparent patterned substrate layer 12 further defines a second via V2. In addition, the display unit 10 further includes a second circuit connection layer 16 and a second circuit bonding layer 17. Specially, the second circuit connection layer 16 is disposed in the second via V2 of the first substrate 122 of the transparent patterned substrate layer 12 and is electrically connected to the drive control circuit layer 121 of the transparent patterned substrate layer 12. The second circuit bonding layer 17 is disposed on a side of the second circuit connection layer 16 facing away from the multiple micro light-emitting components 11 and is electrically connected to the second circuit connection layer 16. In addition, the second via V2 and the first via V1 are disposed at two opposite ends of the transparent patterned substrate layer 12, and the multiple micro light-emitting components 11 are disposed between the second via V2 and the first via V1.

Therefore, the display unit 10 can realize tiling with other display units by means of defining the second via V2 and including the second circuit connection layer 16 disposed in the second via V2, as well as providing the electrical connection among the drive control circuit layer 121, the second circuit bonding layer 17, and the second circuit connection layer 16, thereby obtaining a display screen in larger size.

In conclusion, according to the embodiment 1 of the disclosure, the first via V1 is defined on the first substrate 122, and the first circuit connection layer 13 is disposed in the first via V1, thereby achieving an electrical connection between the first circuit connection layer 13 and the drive control circuit layer 121, thereby solving the problem that a glass substrate cannot define a via and needs to manufacture the circuit on the side thereof, and also solving the problem that the circuit is easily damaged due to the fact that the flexible circuit needs to be bent when the flexible panel is manufactured. In addition, the display unit 10 can realize the tiling with other display units by means of defining the second via V2 and including the second circuit connection layer 16 disposed in the second via V2, as well as providing the electrical connection among the drive control circuit layer 121, the second circuit bonding layer 17, and second circuit connection layer 16, thereby obtaining the display screen in larger size.

### Embodiment 2

As shown in FIG. 3, the embodiment 2 of the disclosure provides a display device 500 including a display substrate 20 and the display unit 10. In an embodiment, the display substrate 20 includes a first side 201 and a second side disposed opposite to the first side 201. The display unit 10 is disposed on the first side 201 of the display substrate 20.

In an embodiment, a first bonding pad 24 is disposed on the first side 201 of the display substrate 20. Specially, the display substrate 20 further includes a second substrate 22 and a transparent conductive layer 23. In an illustrated embodiment, the second substrate 22 is a transparent flexible substrate. Specifically, the second substrate 22 is made of a material selected from the group consisting of polymethyl methacrylate (PMMA), polyimide (PI), polypropylene (PP), polycarbonate (PC), polystyrene (PS), a bismaleimide triazine (BT) material, and a silica gel material, etc. The first bonding pad 24 is a bonding pad that is made of at least one deposited metal selected from the group consisting of copper and aluminum. Specially, a number of the first bonding pads 24 can be one or multiple. The display unit 10 and the first bonding pad 24 are disposed on the same side of the second substrate 22. The first bonding pad 24 is disposed corresponding to the first circuit bonding layer 14 of the display unit 10, and is electrically connected to the first circuit bonding layer 14. The display substrate 20 can be bonded to the display unit 10 through the first bonding pad 24 disposed thereon. It is worth mentioning herein that the display unit 10 can adopt the display unit 10 manufactured in the embodiment 1 of the disclosure, and the structure of the display unit 10 manufactured in the embodiment 1 will not be repeated this time.

The transparent conductive layer 23 is formed by etching a conductive thin film, such as containing multiple transparent metal conductive circuits. The conductive thin film is made of a metal selected from the group consisting of copper, silver, aluminum, platinum, and gold; or the conductive thin film is another metal oxide thin film such as an indium tin oxide (ITO) thin film, an indium zinc oxide (IZO) thin film, or a zinc oxide (ZnO) thin film, and the disclosure is not limited thereto.

The transparent conductive layer 23 is disposed on the second substrate 22 and located between the display unit 10 and the second substrate 22. The transparent conductive layer 23 is disposed on the second substrate 22. The first bonding pad 24 is electrically connected to the transparent conductive layer 23. Specially, the first bonding pad 24 penetrates through the transparent conductive layer 23 and is electrically connected to the first circuit bonding layer 14. In an illustrated embodiment, a number of the first bonding pad 24 can be multiple, and the multiple first bonding pads 24 are correspondingly electrically connected to multiple transparent metal conductive circuits disposed in the transparent conductive layer 23.

In an embodiment, the display device 500 further includes a circuit protection layer 25 disposed between the transparent conductive layer 23 and the display unit 10. Specially, the circuit protection layer 25 covers the transparent conductive layer 23 and exposes the first bonding pad 24. The first bonding pad 24 penetrates the circuit protection layer 25 and is electrically connected to the first circuit bonding layer 14 of the display unit 10. In an illustrated embodiment, the circuit protection layer 25 is made of a transparent insulating material with good heat dissipation property, which is not limited in the disclosure. The disclosure provides the circuit protection layer 25 on the transparent conductive layer 23, which can effectively avoid the circuit damage caused by exposing the transparent conductive layer 23 in the air. In addition, the circuit protection layer 25 with good heat dissipation property of the disclosure can also assist the heat dissipation of the display device 500, thereby prolonging the service life of the display device 500.

Moreover, in an embodiment, the display device 500 further includes a buffer layer 26 disposed between the circuit protection layer 25 and the display unit 10. Specially, the buffer layer 26 is disposed between the transparent patterned substrate layer 12 and the circuit protection layer 25; and the buffer layer 26 covers the circuit protection layer 25 and exposes the first bonding pad 24, thereby providing a bonding area for the first bonding pad 24 and the first circuit bonding layer 14 of the display unit 10 and protecting the first circuit bonding layer 14. In an illustrated embodiment, the buffer layer 26 is made of an inorganic material (e.g., gallium nitride or aluminum nitride, etc.), or an organic material with a buffer and protection effect, which is not limited thereto.

In addition, as shown in FIG. 3, the display device 500 may further include a panel drive circuit 40. In an illustrated embodiment, the panel drive circuit 40 is disposed on a side of the display unit 10, and specifically, the panel drive circuit 40 is disposed on the first side 201 of the display substrate 20. The panel drive circuit 40 includes a chip on film 401 (also referred to as chip on flex, abbreviated as COF), and a driving printed circuit board 402. The panel drive circuit 40 is configured to output a driving signal to the drive control circuit layer 121 and the multiple micro light-emitting components 11, thereby driving the display unit 10. Specifically, the driving printed circuit board 402 is provided with circuits such as controlling time series and a power supply used for driving the chip on film 401 to output the driving signal. In an illustrated embodiment, the chip on film 401 is provided with two bonding ends, one of which is used to bond to the first bonding pad 24 and another of which is used to bond to the driving printed circuit board 402. When the display unit 10 is bonded to the first bonding pad 24, the display unit 10 may receive the driving control signal transmitted by the panel drive circuit 40 through the first bonding pad 24, so as to realize the display control of the display unit 10. It should be noted that a material that can achieve the bonding effect of the chip on film 401, the driving printed circuit board 402, and the first bonding pad 24 can be determined as the metal solder, the ACF film layer, or other bonding materials mentioned in the embodiment 1, which is not limited thereto.

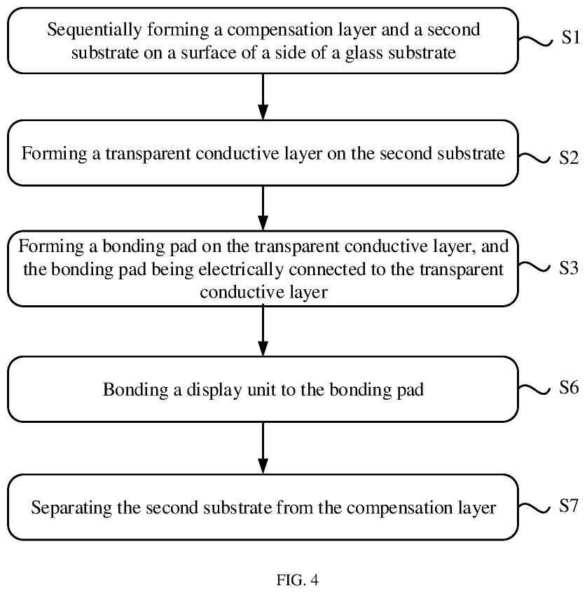

In addition, as shown in FIG. 4, the embodiment 2 of the disclosure further provides a manufacturing method of the display device 500, which specifically includes the following steps:

step 1, sequentially forming a compensation layer and a second substrate on a surface of a side of a glass substrate;

step 2, forming a transparent conductive layer on the second substrate;

step 3, forming a bonding pad on the transparent conductive layer, and the bonding pad being electrically connected to the transparent conductive layer;

step 6, bonding the first circuit bonding layer of the display unit as mentioned in any one of the foregoing embodiments to the bonding pad; and

step 7, separating the second substrate from the compensation layer.

Specifically, the step 1 includes: cleaning the glass substrate and forming the compensation layer on the surface of the side of the glass substrate; and the compensation layer is made of a black organic material or a gray organic material. In an embodiment, the compensation layer is made of amorphous silicon (a-Si), silicon nitride (SiNₓ), or silicon oxide (SiOₓ). The second substrate is formed on the surface of the compensation layer facing away from the glass substrate, and the second substrate is made of a material selected from the group consisting of polymethyl methacrylate (PMMA), polyimide (PI), polypropylene (PP), polycarbonate (PC), polystyrene (PS), BT material, and silica gel material.

In the step 3, a number of the bonding pad can be multiple. The multiple bonding pads are electrically conductive through the transparent conductive layer.

In the above steps, the multiple-layer structure is prepared by existing layer production process, and the multiple layers are made of the materials described in the embodiment 1.

The step 7 specially includes: separating the glass substrate and removing the compensation layer. Due to the fact that the compensation layer is only in contact with the second substrate, the problem of metal breakage caused by subsequent laser lift-off operation can be avoided, the flatness and cleanliness of the surface of the side, facing towards the glass substrate, of the second substrate after the laser lift-off operation are protected, and the surface treatment for the second substrate is not needed, thereby saving energy consumption.

In addition, as shown in FIG. 5, the manufacturing method of the display device provided in the embodiment 2 further includes: step 4, pasting a circuit protection layer on the transparent conductive layer, and the circuit protection layer covering the transparent conductive layer and the bonding pad penetrating through the circuit protection layer.

Furthermore, as shown in FIG. 5, before the step 6, the manufacturing method of the display device provided in the embodiment 2 further includes: step 5, providing a buffer layer on the circuit protection layer, and the buffer layer covering an area, except the bonding pad, of the circuit protection layer.

Specifically, the circuit protection layer is made of a transparent insulating material with good heat dissipation property, avoids the problem of circuit damage caused by the exposure of the transparent conductive layer in the air, assists the heat dissipation of the display device, and prolongs the service life of the display device. The buffer layer is disposed on the side of the second substrate facing away from the compensation layer, and the buffer layer covers the bonding pad and the circuit protection layer. The buffer layer defines a via to penetrate through the buffer layer and to expose the bonding pad in a direction perpendicular to the second substrate for bonding the display unit. The buffer layer is made of an inorganic material (e.g., gallium nitride or aluminum nitride, etc.), or an organic material with a buffer and protection effect, and the disclosure is not limited thereto.

Finally, the above-mentioned manufacturing method of the display device further includes: step 8, bonding the bonding pad and the panel drive circuit. The panel drive circuit is bonded to any one of the multiple bonding pads on the transparent conductive layer, which is not limited to the disclosure. The specific structural composition and function of the panel drive circuit are described above, and details are not described herein again.

In summary, the embodiment 2 of the disclosure has the following beneficial effects: on one hand, in the display device provided by the embodiment 2 of the disclosure, the panel drive circuit and the drive control circuit layer are electrically connected through the circuit connection layer and the circuit bonding layer provided by the display unit, which makes the bonding area of the display device be disposed between the second substrate and the first substrate, thereby avoiding the problems that the circuit needs to be manufactured on the side of the display unit, and the circuit is easy to break after flexible bending. On the other hand, the embodiment 2 of the disclosure further provides the manufacturing method of the display device, the disclosure provides the compensation layer between the glass substrate and the flexible substrate, the problem of metal breakage caused by stripping operation in subsequent laser glass operation is avoided, the flatness and cleanliness of the side, facing towards the glass substrate, of the stripped flexible substrate are protected, and energy consumption is saved.

### Embodiment 3

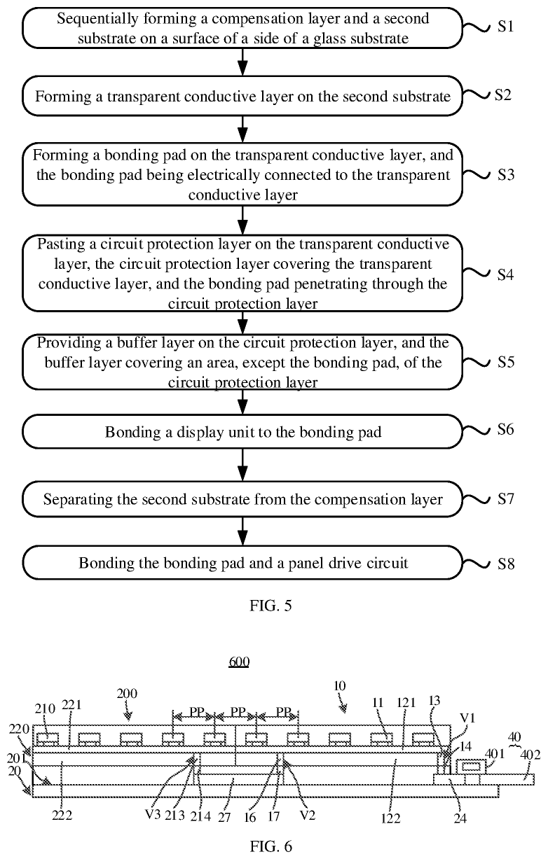

With reference to FIG. 1 to FIG. 3 and FIG. 6, the embodiment 3 of the disclosure provides a display device 600. The display device 600 provided by the embodiment 3 is different from the display device 500 provided by the embodiment 2 in that the display device 600 of the embodiment 3 includes multiple display units, that is, a large-size display screen is formed by tiling the multiple display units. In the embodiment 3, two display units are taken as an example, namely that, on the basis of the foregoing embodiment 2, the display device 600 of the embodiment 3 further includes a second display unit 200 (with reference to FIG. 6). The second display unit 200 can be the display unit in the foregoing embodiment 1. The display unit 10 and the second display unit 200 are disposed on the display substrate 20. Specifically, the display unit 10 and the second display unit 200 are arranged side by side on the first side 201 of the display substrate 20 for tiling to form the large-size display screen.

Specifically, as shown in FIG. 6, the second display unit 200 may include: a transparent patterned substrate layer 220, multiple micro light-emitting components 210, a third circuit connection layer 213, and a third circuit bonding layer 214. In an illustrated embodiment, the transparent patterned substrate layer 220 includes a first substrate 222 and a drive control circuit layer 221. The first substrate 222 defines a third via V3 thereon. Specially, structures and connection relationships of the transparent patterned substrate layer 220, the multiple micro light-emitting components 210, the third circuit connection layer 213, the third circuit bonding layer 214, the first substrate 222, the drive control circuit layer 221, and the third via V3 can refer to the description in the foregoing embodiment 1, and a structure of the display substrate 20 can refer to the description in the forgoing embodiment 2, which are repeated herein.

In addition, as shown in FIG. 6, the first substrate 122 of the transparent patterned substrate layer 12 of the display unit 10 further defines a second via V2, and the second via V2 and the first via V1 are disposed at two opposite ends of the first substrate 122 on the transparent patterned substrate layer 12. Moreover, the display unit 10 may further include a second circuit connection layer 16 and a second circuit bonding layer 17. In an illustrated embodiment, the second circuit connection layer 16 is disposed in the second via V2 of the first substrate 122 of the transparent patterned substrate layer 12, and the second circuit connection layer 16 is electrically connected to the drive control circuit layer 121 of the transparent patterned substrate layer 12. The second circuit bonding layer 17 is disposed on a side of the second circuit connection layer 16 facing away from the multiple micro light-emitting components 11, and the second circuit bonding layer 17 is electrically connected to the second circuit connection layer 16, and the multiple micro light-emitting components 11 are disposed between the second via V2 and the first via V1.

Furthermore, in addition to the first bonding pad 24, the display panel 10 is further provided with a second bonding pad 27, the second bonding pad 27 is disposed corresponding to the second circuit bonding layer 17 and is electrically connected to the second circuit bonding layer 17. Namely, the first circuit bonding layer 14 is electrically connected to the second circuit bonding layer 17. The third circuit bonding layer 214 of a second display unit 200 is electrically connected to the second bonding pad 27. Therefore, the tiling between the display unit 10 and the second display unit 200 has been achieved, while saving driving costs.

It is worth mentioning that the display device 600 may further include more display units, such as the display unit 10, and more bonding pads are arranged at corresponding positions on the display substrate 20 to bond to the corresponding display units 10, and then the display screen with a larger size can be tiled, and the application market of the product (i.e., the display device) is expanded.

Furthermore, as shown in FIG. 6, a pixel spacing between two adjacent micro light-emitting components 11 on the display unit 10 is PP, a pixel spacing between two adjacent micro light-emitting components 11 on the second display unit 200 is also PP, and a pixel spacing between the two micro light-emitting components 11 that are located at an outermost edge of the display unit 10 and the second display unit 200 is also PP. In this way, seamless tiling of the display units (i.e., the display unit 10 and the second display unit 200) can be achieved.

In addition, it may be understood that the foregoing embodiments are merely illustrative descriptions of the disclosure, and the technical solutions of the various embodiments may be combined and used in any combination without departing from the objectives of the disclosure.

It should be noted that the above embodiments are merely used to illustrate the technical solutions of the disclosure and are not limited thereto. Although the disclosure has been described in detail with reference to the foregoing embodiments, it should be understood by those skilled in the related art that they can still modify the technical solutions recited in the foregoing embodiments or replace some of the technical features therein. However, these modifications or replacements do not make an essence of the corresponding technical solutions separate from the spirit and scope of the technical solutions of the embodiments of the disclosure.

What is claimed is:

1. A display unit, comprising:
a transparent patterned substrate layer, wherein the transparent patterned substrate layer defines a first via;
a plurality of micro light-emitting components, disposed on the transparent patterned substrate layer and electrically connected to the transparent patterned substrate layer;
a first circuit connection layer, disposed in the first via of the transparent patterned substrate layer and electrically connected to the transparent patterned substrate layer; and
a first circuit bonding layer, disposed on a side of the first circuit connection layer facing away from the plurality of micro light-emitting components and electrically connected to the circuit connection layer.

2. The display unit according to claim 1, wherein the display unit further comprises: a packaging layer disposed on the transparent patterned substrate layer; and the packaging layer covers the plurality of micro light-emitting components.

3. The display unit according to claim 1, wherein the transparent patterned substrate layer comprises:
a first substrate, wherein the first via penetrates through the first substrate; and
a drive control circuit layer, disposed on a side of the first substrate, wherein the drive control circuit layer is disposed between the first substrate and the plurality of micro light-emitting components; the plurality of micro light-emitting components are electrically connected to the drive control circuit layer; and the first circuit bonding layer is disposed on a side of the first substrate facing away from the drive control circuit layer, and the first circuit connection layer is electrically connected to the plurality of micro light-emitting components through the drive control circuit layer.

4. The display unit according to claim 1, wherein the transparent patterned substrate layer further defines a second via;
wherein the display unit further comprises: a second circuit connection layer and a second circuit bonding layer;
wherein the second circuit connection layer is disposed in the second via of the transparent patterned substrate layer and is electrically connected to the transparent patterned substrate layer; and
wherein the second circuit bonding layer is disposed on a side of the second circuit connection layer facing away from the plurality of micro light-emitting components and is electrically connected to the second circuit connection layer.

5. The display unit according to claim 4, wherein the second via and the first via are disposed at two opposite ends of the transparent patterned substrate layer, and the plurality of micro light-emitting components are disposed between the second via and the first via.

6. The display unit according to claim 3, wherein the transparent patterned substrate layer further defines a second via; and
wherein the second via penetrates through the first substrate of the transparent patterned substrate layer to the drive control circuit layer and disposed opposite to the first via.

7. The display unit according to claim 6, wherein the display unit further comprises: a second circuit connection layer and a second circuit bonding layer;
wherein the second circuit connection layer is disposed in the second via of the transparent patterned substrate layer and electrically connected to the first substrate;
wherein the second circuit bonding layer is disposed on a side of the second circuit connection layer facing away from the first substrate and electrically connected to the second circuit connection layer.

8. The display unit according to claim 7, wherein the second circuit connection layer is disposed in a same layer with the first circuit connection layer, and the second circuit bonding layer is disposed in a same layer with the first circuit bonding layer.

9. The display unit according to claim 1, wherein the number of the first via is multiple, and the multiple first vias are disposed around edges of the first substrate.

10. The display unit according to claim 1, wherein the number of the first via is multiple, and the multiple first vias are disposed at two opposite ends of the first substrate.

11. A display device, comprising:
a display substrate;
a first bonding pad, disposed on a side of the display substrate; and
a first display unit, wherein the first display unit is the display unit according to claim 1, and the first display unit is disposed on the side of the display substrate;
wherein the first bonding pad is disposed corresponding to the first circuit bonding layer of the first display unit and is electrically connected to the first circuit bonding layer of the first display unit.

12. The display device according to claim 11, wherein the transparent patterned substrate layer of the first display unit further defines a second via, the second via and the first via are disposed on two opposite ends of the transparent patterned substrate layer, and the plurality of micro light-emitting components are disposed between the second via and the first via;
wherein the first display unit further comprises: a second circuit connection layer and a second circuit bonding layer; the second circuit connection layer is disposed in the second via of the transparent patterned substrate layer and is electrically connected to the transparent patterned substrate layer; and the second circuit bonding layer is disposed on a side of the second circuit connection layer facing away from the plurality of micro light-emitting components and is electrically connected to the second circuit connection layer; and
wherein the display device further comprises a second bonding pad disposed on the side of the display substrate, and the second bonding pad is disposed corresponding to the second circuit bonding layer and is electrically connected to the second circuit bonding layer.

13. The display device according to claim 11, wherein the display substrate comprises:
a second substrate, wherein the first display unit and the first bonding pad are disposed on a same side of the second substrate; and
a transparent conductive layer, disposed on the second substrate and disposed between the first bonding pad and the second substrate, wherein the transparent conductive layer is electrically connected to the first bonding pad.

14. The display device according to claim 13, wherein the display device further comprises: a circuit protection layer, the circuit protection layer is disposed between the transparent conductive layer and the first display unit, the circuit protection layer covers the transparent conductive layer; and the first bonding pad penetrates through the circuit protection layer and is electrically connected to the first circuit bonding layer of the first display unit.

15. The display device according to claim 14, wherein the display device further comprises: a buffer layer disposed between the circuit protection layer and the first display unit.

16. The display device according to claim 11, wherein the display device further comprises: a panel drive circuit disposed on the side of the display substrate and electrically connected to the first bonding pad.

17. The display device according to claim 12, wherein the display device further comprises: a second display unit disposed on the side of the display substrate; and the second display unit is tiled with the first display unit; a structure of the second display unit is the same as that of the first display unit, and the first circuit bonding layer of the second display unit is electrically connected to the second bonding pad.

18. The display device according to claim 16, wherein the panel drive circuit comprises: a chip on film and a driving printed circuit board; and
wherein the chip on film is provided with two bonding ends, one of the two bonding ends is bonded to the first bonding pad and the other bonding end is bonded to the driving printed circuit board.

19. A manufacturing method of a display device, comprising the following steps:
sequentially forming a compensation layer and a second substrate on a side of a glass substrate;
forming a transparent conductive layer on the second substrate;
forming a bonding pad on the transparent conductive layer, wherein the bonding pad is electrically connected to the transparent conductive layer;
bonding the first circuit bonding layer of the display unit according to claim 1 to the bonding pad; and
separating the second substrate from the compensation layer.

20. A display device, comprising:
a display substrate;
a plurality of display units, disposed on a side of the display substrate; wherein each of the plurality of display units comprises:
a transparent patterned substrate layer, wherein the transparent patterned substrate layer defines a first via and a second via;
a plurality of micro light-emitting components, disposed on the transparent patterned substrate layer and between the first via and the second via; wherein the plurality of micro light-emitting components are electrically connected to the transparent patterned substrate layer;
a first circuit connection layer, disposed in the first via and electrically connected to the transparent patterned substrate layer;
a first circuit bonding layer, disposed on a side of the first circuit connection layer facing away from the plurality of micro light-emitting components and electrically connected to the first circuit connection layer;
a second circuit connection layer, disposed in the second via and electrically connected to the transparent patterned substrate layer; and
a second circuit bonding layer, disposed on a side of the second circuit connection layer facing away from the plurality of micro light-emitting components and electrically connected to the second circuit connection layer; and
a plurality of bonding pads, disposed on the side of the display substrate; wherein the plurality of bonding pads are disposed corresponding to the first circuit bonding layers and the second circuit bonding layers of the plurality of display units; and the plurality of display units are tiled through electrically connecting the plurality of bonding pads with the corresponding first circuit bonding layers and the corresponding second circuit bonding layers of the plurality of display units.
